(19) United States
(12) Patent Application Publication
(10) Pub. No.: US 2016/0315236 A1
(43) Pub. Date: Oct. 27, 2016

(54) ILLUMINATING FILM STRUCTURE

(71) Applicant: FLEXBRIGHT OY, Kangasala (FI)

(72) Inventors: Pekka Makkonen, Kangasala (FI); Kimmo Keranen, Oulu (FI)

(21) Appl. No.: 15/105,462

(22) PCT Filed: Dec. 17, 2014
(86) PCT No.: PCT/FI2014/051016

§ 371 Date: Jun. 16, 2016

(30) Foreign Application Priority Data
Dec. 18, 2013 (FI) 20136284

(51) Int. Cl. H01L 33/60; H05K 1/18; H05K 9/00; H05K 3/32; H01L 25/075; H05K 3/28; H01L 33/50; H01L 33/56; H01L 33/62; H05K 1/02; H05K 1/09

(52) U.S. Cl. CPC H01L 33/60; H05K 1/028; H05K 1/189; H05K 9/0073; H05K 3/321; H05K 1/092; H05K 1/183; H05K 1/186; H05K 3/281; H01L 33/502; H01L 33/56; H01L 33/62; H01L 25/0753; H05K 2201/10106; H05K 2201/10674; H05K 2201/2054; H01L 2933/0041; H01L 2933/005; H01L 2933/0058; H01L 2933/0066

(57) ABSTRACT

A flexible and illuminating film structure includes a flexible single polymer foil; a flexible electrically conductive pattern layer with contact areas for components on a first side of the polymer foil; at least one cavity which extends though the polymer foil from a second side to the contact areas of the conductive pattern layer on the first side and overlaps with at least one contact area; at least one non-organic light emitting diode flip-chip in the at least one cavity and electrically coupled with the contact areas; and a first flexible shielding foil layered on the second side of the polymer foil.

### CROSS-REFERENCE TO RELATED APPLICATION

This application is a National Stage application of International Application No. PCT/FI2014/051016, filed Dec. 17, 2014, which claims priority to Finnish Application No. 20136284, filed Dec. 18, 2013, which are incorporated by reference herein in their entirety.

### BACKGROUND

1. Field

The invention relates to an illuminating film structure.

2. Description of the Related Art

Organic LEDs or OLEDs offer a possibility to make a relatively thin and illuminating film which may in principle be flexible. Organic materials, however, require a very good protection against environmental oxygen and moisture in order to have long enough life expectancy from practical point of view. That is why OLEDs are closed between two glass plates which results in loss of thinness and flexibility.

In the manufacturing process of SMD (Surface-Mounted Device) LED (Light Emitting Diode) components and even bare chips can be bonded on the surface of polymer substrates for achieving relatively thin illumination structure which is flexible to certain extent. The total thickness of the structure is mainly determined by the sum of thickness of the LED device and thickness of the polymer substrate(s). The total thickness causes an absolute limit for the flexibility of the illumination surface.

A plurality of applications, however, requires more flexibility and thinner structures than possible at the moment. Thus, there is need for improvement in thickness and flexibility of these illuminating films.

### SUMMARY

The present invention seeks to provide an improved flexible and illuminating film structure and a manufacturing method thereof. According to an aspect of the present invention, there is provided an illuminating film structure as specified in claim 1.

According to another aspect of the present invention, there is provided a manufacturing method in claim 6.

The invention provides an improvement in flexibility and thickness in the light emitting films which enables their installation on surfaces of largely varying shapes.

### BRIEF DESCRIPTION OF THE DRAWINGS

Example embodiments of the present invention are described below, by way of example only, with reference to the accompanying drawings, in which

FIG. 1 illustrates an example of a flexible and illuminating film structure;

FIG. 2 illustrates a flexible single polymer foil and a flexible and electrically conductive layer;

FIG. 3 illustrates of the flexible single polymer foil and the flexible and electrically conductive layer which is patterned;

FIG. 4 illustrates the flexible single polymer foil and the flexible and electrically conductive layer with connecting areas revealed;

FIG. 5 illustrates of the flexible single polymer foil and the flexible and electrically conductive layer on a second flexible shielding foil;

FIG. 6 illustrates adhesives on the connecting areas;

FIG. 7 illustrates LEDs bonded to the connecting areas;

FIG. 8 illustrates a gap between at least one light emitting diode chip and walls of the cavity filled with elastic electrically non-conductive material;

FIG. 9 illustrates a luminescent foil over the flexible single polymer foil;

FIG. 10 illustrates an example of a roll-to-roll process; and

FIG. 11 illustrates a flow chart of a manufacturing method.

### DETAILED DESCRIPTION

The following embodiments are only examples. Although the specification may refer to “an” embodiment in several locations, this does not necessarily mean that each such reference is to the same embodiment(s), or that the feature only applies to a single embodiment. Single features of different embodiments may also be combined to provide other embodiments. Furthermore, words “comprising” and “including” should be understood as not limiting the described embodiments to consist of only those features that have been mentioned and such embodiments may contain also features/structures that have not been specifically mentioned.

It should be noted that while Figures illustrate various embodiments, they are simplified and only show some structures and/or functional entities. The connections shown in the Figures may refer to electrical and/or physical connections. It is apparent to a person skilled in the art that the described apparatus may also comprise other functions and structures than those described in Figures and text. It should be appreciated that details of some functions, structures, power supply and the signalling are irrelevant to the actual invention. Therefore, they need not be discussed in more detail here.

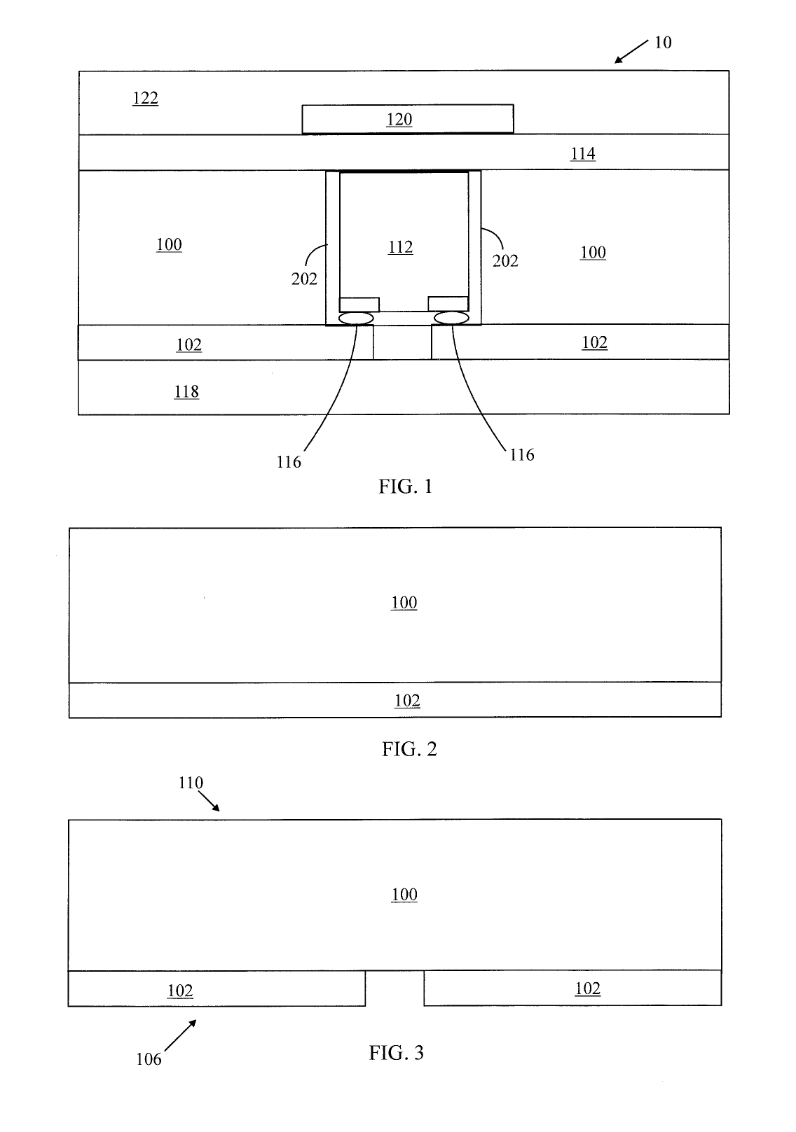

FIG. 1 shows an example of the flexible and illuminating film structure 10. FIGS. 2 to 9 show examples of different phases of a manufacturing process of the illuminating film structure 10.

In order to decrease the thickness of the structure and improve the flexibility of the illuminating film 10 the total thickness of the illumination film structure 10 has to be kept thin.

The flexible and illuminating film structure 10 is a layered structure the thickness of which may be less than about 1 mm. The thickness may be about 0.1 mm or even less, for example. Although the a thin film is usually wanted, the film may be made thicker such that the thickness is about 2 mm, for example.

The flexible and illuminating film structure 10 may not only be thin but it may also have a small radius of curvature. The radius of curvature may be less than 10 mm, for example. The radius of curvature may go down to about 1 mm, for example. The surface on which the flexible and illuminating film 10 is placed may be planar, curved or even double curved.

As shown in FIG. 2, the flexible and illuminating film structure 10 comprises a flexible single polymer foil 100 which can be considered as a substrate of the film 10. The foil 100 may comprise plastic such as polyimide (PI), polyethylene terephthalate (PET), polyethylene naphthalate (PEN), polycarbonate (PC), liquid crystal polymer (LCP) or the like, for example. The the flexible and illuminating film structure 10 also comprises a flexible and electrically conductive layer 102 which can be patterned for making conductors of an electric circuit which enable the operation of the illuminating film structure 10.

FIG. 3 illustrates an example of the flexible and illuminating film 10 which has the flexible and electrically conductive layer 102 patterned. The electrically conductive pattern has contact areas 104 for components.

In an embodiment, the electrically conductive and patterned layer 102 may comprise a metallized polymer layer structure on a first side 106 of the polymer foil 100. The metallized polymer layer structure may be laminated on the first side 106 of the polymer foil 100. The metallized polymer layer structure on the first side 106 of the polymer foil 100 can be processed by laminating conductive patterns on top of polymer foil using transfer printing method. Another possible method is to combine evaporation and electrolytic deposition. A very straightforward method is to utilize commercially available laminated metallic, typically copper or aluminium, coated polymer foils in which conductive traces are patterned by etching, mechanical machine tooling or laser ablation, for example. The metallized polymer layer may then have the pattern of the circuitry of the conductors and the contact areas 104.

In an embodiment, the electrically conductive layer 102 may be made by printing the pattern of the circuitry of the conductors and the contact areas 104 with at least one printable conductive ink. FIG. 3 illustrates these two embodiments of the electrically conductive pattern 102.

The conductors are not shown in details in Figures but they are included in the conductive and patterned layer 102.

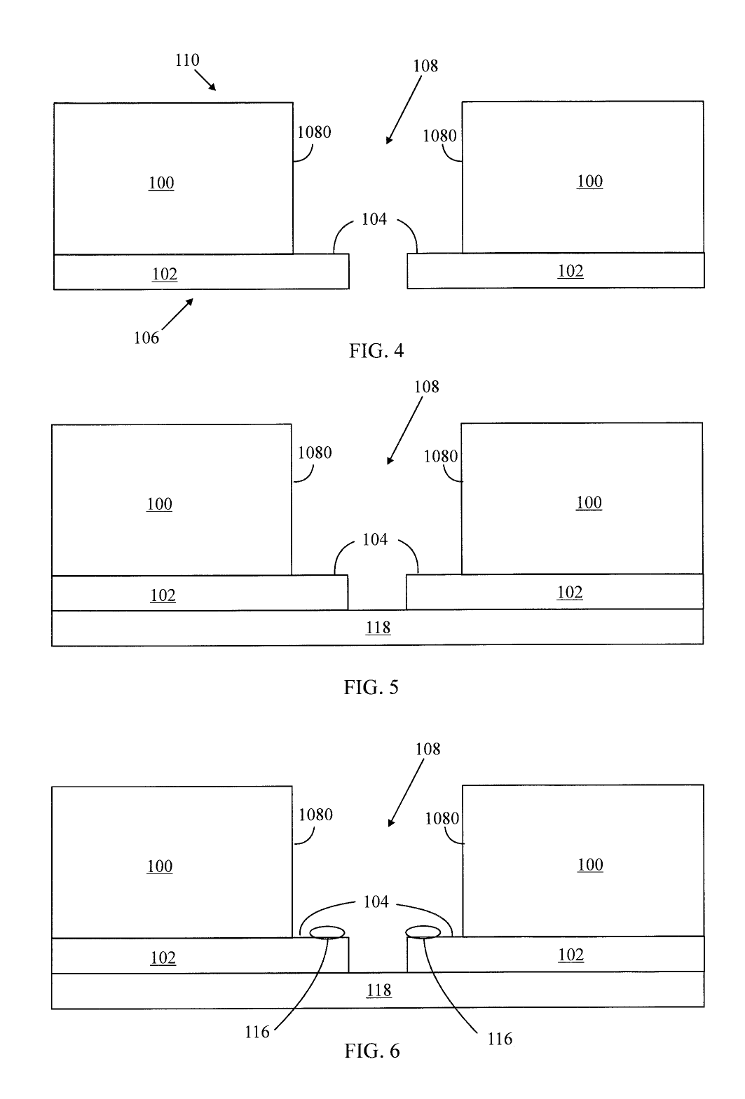

As shown in FIGS. 1 and 4, the flexible and illuminating film 10 comprises at least one cavity 108 in the polymer foil 100. The at least one cavity 108 extends though the polymer foil 100 from a second side 110 to the contact areas 104 of the conductive pattern 102 on the first side 106. The bottom surface of each cavity 108 overlaps at least partly with at least one contact area 104. The at least one cavity 108 is made in order to reveal the contact areas 104 for enabling mounting of components such as light emitting diode chips and other electrical components via the at least one cavity 108 from a second side 110. The at least one cavity 108 also enables any action of bonding the components, for example.

In an embodiment shown in FIGS. 1, 5 to 9, the film structure comprises a second flexible shielding foil 118 on the conductive pattern 102 such that the conductive pattern 102 is between the polymer foil 100 and the second shielding foil 118. The second shielding foil 118 may have a mirror like metallic coating for reflecting optical radiation transmitted by the light emitting diode chips 112. The second shielding foil 118 may mechanically support the polymer foil 100 and protect the polymer foil 100 mechanically. The second shielding foil 118 may be laminated on the first side 106 of the film structure 10.

In an embodiment shown in FIGS. 1, 6 to 9, the film structure 10 may comprise a conductive adhesive 116 between the at least one light emitting diode chip 112 and the contact areas 104. The conductive adhesive 116 may be dispensed through the cavity 108 from the second side 110.

In an embodiment, the conductive adhesive 116 is isotropic glue. In an embodiment, the conductive adhesive 116 is anisotropic glue.

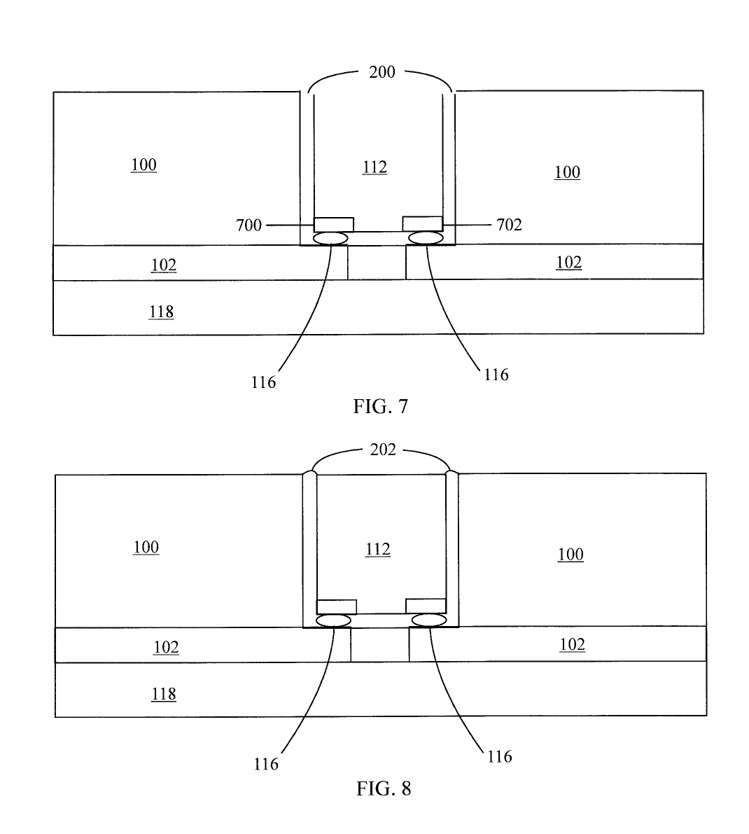

As shown in FIGS. 1 and 7, the flexible and illuminating film structure 10 comprises at least one non-organic light emitting diode flip-chip 112. In an organic light emitting diode (OLED) the operational structure, which emits light when electric current is fed to the OLED, has an organic compound. The organic compound is generally determined to be material which has at least one chemical compound of carbon. The non-organic light emitting diode doesn't have a chemical compound of carbon in the operational structure which emits light.

The light emitting diode chips 112 are placed in the cavities 108 from the second side 110. Each of the at least one light emitting diode chip 112 may be placed in a cavity of the at least one cavity 108. Each of the at least one light emitting diode chip 112 is electrically coupled with the contact areas 104. The contact areas 104 may also be called pads. The flip-chip light emitting diode chips 108 may have anode 700 and cathode 702 on the same side or surface. The anode 700 and the cathode 702 are the electric terminals of a light emitting diode chip 112. By using inorganic light emitting chips 112 the brightness of the film 10 may be over 1000 cd/m² or even more than 5000 cd/m². For example, Luxenon 3535L SMD led, which has 1 mm×1 mm chip covered with phosphorus, may output 30 to 35 lm. If it is assumed that the maximum output angle of light is about 160°, the led outputs light in a solid angle Ω=2*π[1−cos(160°/2)]sr=5.19 sr. The brightness of the led is thus about 30 lm/5.19 sr=5.8 cd. To have 1000 cd/m² requires thus about 173 chips of leds. For a square meter 14×14 led chips may then be used. The pitch or distance between led chips is then about 7.9 cm. In order to have 5000 cd/m² requires five times more led chips which results in 865 leds. By round numbers that is about 900 led chips which result in a pitch 3.4 cm. The inorganic light emitting diode chips 112 are durable and they can be bonded to printed conductors on the thin and flexible substrate foil 100 with modern roll-to-roll bonders, for example.

In this application, the light emitting diode chip 112 is a light emitting diode die that has not been packaged or encapsulated. That is, the light emitting diode chip 112 includes the semiconductor structure but not a case, capsule or housing although the packed light emitting diode chips typically comprise a plastic case, capsule or housing, for example. The light emitting diode chips emit optical radiation. The optical radiation may be ultraviolet light, visible light or infrared light. The light emitting diode chips 112 may comprise monochromatic light emitting diode chips or RGB (Red Green Blue) light emitting diode chips. According to the chosen type of the light emitting diode chips 112 it is possible to electrically control the illumination color of film structure 10. The light emitting diode chips 112 may be dense or sparse depending on the application of the illuminating film 100. The sparse distribution of light emitting diode chips 112 makes the manufacturing faster and leads to low manufacturing costs.

When the light emitting diodes 112 are dense their distance from each other or pitch is limited on the basis of the sizes of the chips. Another limitation comes from the conductor technology and the achievable sheet resistance. The resistance of bulk copper, aluminum, silver and/or gold is much better than that of silver ink, for example. That is why eching and laminating those metals results in higher density. A high density is achieved when the pitch is about 1.5 times chip size. By using printing methods a high density is achieved when the pitch is about 2 times chip size. A sparse distribution of chips may be however sparse, in principle, but the intensity and evenness of illumination determine how sparse the chips can be in the film structure 10.

In an embodiment shown in FIGS. 1, 7 and 8 a gap 200 between at least one light emitting diode chip 112 and walls 1080 of the cavity 108 may be filled with elastic electrically non-conductive material 202. In an embodiment, the at least one light emitting diode chip 112 may be surrounded by the elastic electrically non-conductive material 202. The elastic electrically non-conductive material 202 may be dispensed to each gap 200.

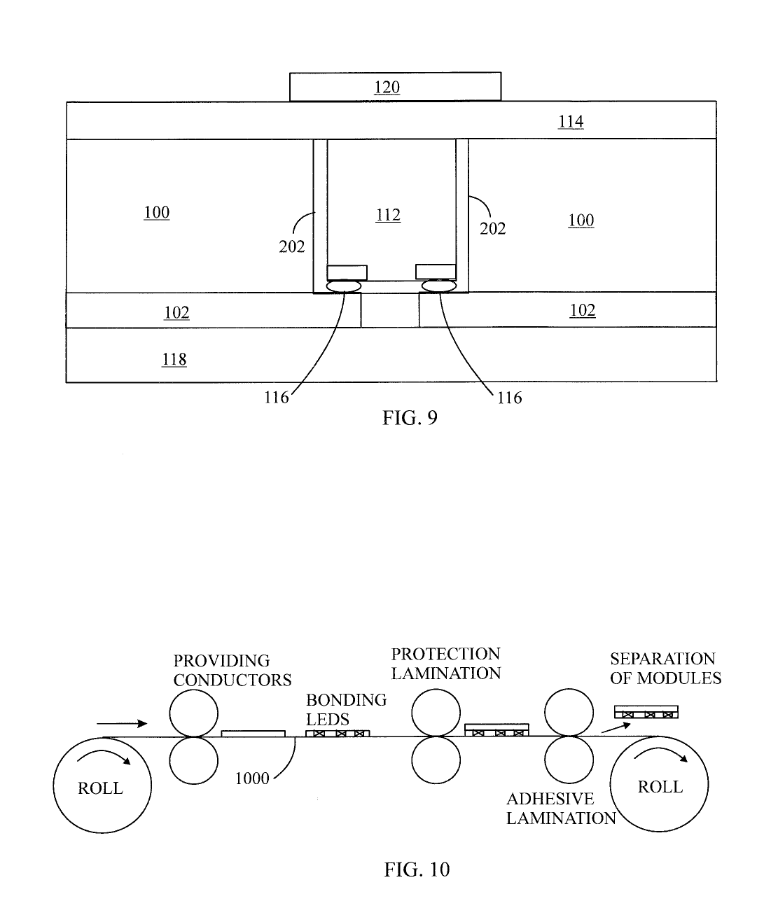

As shown in FIGS. 1 and 9, the flexible and illuminating film structure 10 comprises a first flexible shielding foil 114 layered on the second side 110 of the polymer foil 100. The first shielding foil 114 may be of plastic, epoxy or silicon. The first shielding foil 114 may be laminated on the polymer foil 100 having the light emitting chips 112 therein. Epoxy and silicon may be dispensed on the polymer foil 100. The first shielding foil 114 may protect the light emitting chips 112 and other components mechanically. The first shielding foil 114 may also guide the light in a desired manner inside the flexible and illuminating film 10 and it may also guide light in a desired direction outwards from the flexible and illuminating film 10.

In an embodiment illustrated in FIGS. 1 and 9, the the first shielding foil 114 may comprise a luminescent foil 120 placed over the the at least one light emitting diode chip 112. The luminescent foil 120 may be laminated on a layer of the first shielding foil 114 which may comprise at least one layer. If the first shielding foil 114 comprises several layers 122, 124, the luminescent foil 120 may reside between two layers of the first shielding foil 114.

In an embodiment, the luminescent foil 114 may be a phosphorus foil. In an embodiment, the luminescent foil 114 may be patterned according to the conductive layer 102.

The flexible illuminating film structure 10 may have a wide illuminating surface. The area of the flexible illuminating film structure 10 may be one or more square meters. Alternatively, the area of the flexible illuminating film structure 10 may be one or more square decimeters. In an embodiment, the area of the flexible illuminating film structure 10 may be one or more square centimeters.

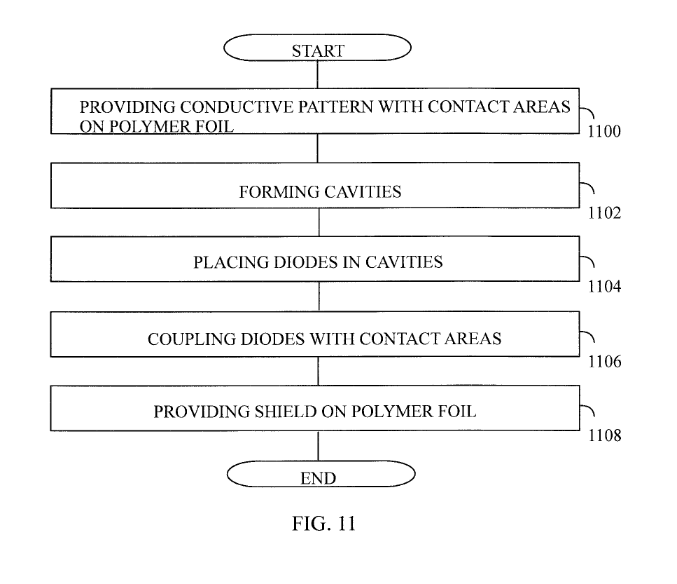

The flexible illuminating film structure 10 may be manufactured using a roll-to-roll (R2R) method which is illustrated in FIG. 10. Such a processing enables manufacturing wide, thin and flexible illuminating film which has a long life expectancy. Also the efficiency and brightness can be made better than those of the present OLEDs. The life expectancy of the flexible illuminating film 10 may be more than 10,000 hours or even 100,000 hours.

The flexible illumination film 10 may shortly be described as follows:
substrate film 100 is based on polymers
substrate film is thin (less than 100 μm)
substrate film may have wide surface
conductors may be printed on substrate film 10 using printing technology or etching of a foil with metal may be used
LEDs are inorganic LED chips which are not packed
LED couplings to conductors is based on bonding technology
manufacturing process uses roll-to-roll method
brightness is over 1000 cd/m² or even more than 5000 cd/m².

FIG. 11 illustrates an example of a flow chart of the manufacturing method. In step 1100, a flexible electrically conductive pattern layer 102 with contact areas 104 for components on a first side 106 of a polymer foil 100 is provided. In step 1102, at least one cavity 108 which extends though the polymer foil 100 from the second side 110 to the contact areas 104 of the conductive pattern layer 102 on the first side 106 is formed, for revealing the contact areas 104 and for performing mounting of components via the at least one cavity 108 from a second side 110. In step 1104, each of at least one non-organic light emitting diode flip-chip 112 is placed in an cavity of the at least one cavity 108. In step 1106, the at least one non-organic light emitting diode flip-chip 112 is coupled electrically with the revealed contact areas 104. In step 1108, a first flexible shielding foil 114 is provided on the second side 110 of the polymer foil 100.

It will be obvious to a person skilled in the art that, as technology advances, the inventive concept can be implemented in various ways. The invention and its embodiments are not limited to the example embodiments described above but may vary within the scope of the claims.

What is claimed is:

1. A flexible and illuminating film structure wherein the flexible and illuminating film structure comprises:
a flexible single polymer foil;
a flexible electrically conductive pattern layer with contact areas for components, the conductive pattern layer being a layer on a first side of the polymer foil;
at least one cavity which extends through the polymer foil from a second side to the contact areas of the conductive pattern layer on the first side, each cavity overlapping with at least one contact area of the conductive pattern;
at least one non-organic light emitting diode flip-chip in the at least one cavity and electrically coupled with the contact areas a gap between the non-organic light emitting diode flip-chip and walls of the cavity being filled with elastic electrically non-conductive material; and
a first flexible shielding foil layered on the second side of the polymer foil for mechanical protection and light guidance.

2. The film structure of claim 1, wherein the electrically conductive pattern layer comprises at least one of the following: a metallized polymer structure and conductors based on at least one printable conductive ink.

3. The film structure of claim 1, wherein the film structure comprises a conductive adhesive between the at least one light emitting diode chip and the contact areas.

4. The film structure of claim 1, wherein the film structure comprises a second flexible shielding foil on the conductive pattern layer such that the conductive pattern layer is between the polymer foil and the second shielding foil.

5. The film structure of claim 1, wherein the the first shielding foil comprises a luminescent foil placed on the the at least one light emitting diode chip.

6. A method of manufacturing a flexible and illuminating film structure, wherein the method comprises:
providing a flexible electrically conductive pattern layer with contact areas for components on a first side of a polymer foil;
forming at least one cavity which extends through the polymer foil from the second side to the contact areas of the conductive pattern layer on the first side, for revealing the contact areas and for performing mounting of components via the at least one cavity from a second side;
placing each of at least one non-organic light emitting diode flip-chip in an cavity of the at least one cavity;
coupling electrically the at least one non-organic light emitting diode flip-chip with the revealed contact areas of the conductive pattern;
filling a gap between the non-organic light emitting diode flip-chip and walls of the cavity with elastic electrically non-conductive material; and
providing a first flexible shielding foil on the second side of the polymer foil for mechanical protection and light guidance.

7. The method of claim 6, wherein further comprising forming the electrically conductive pattern layer with at least one of the following: (1) laminating a metallized polymer structure to the first side of the polymer foil and patterning the metallized polymer structure, and (2) printing conductors with at least one conductive ink on the first side of the polymer foil.

8. The method of claim 6, wherein further comprising:
coupling electrically the at least one non-organic light emitting diode flip-chip with the contact areas by dispensing conductive adhesive to the contact areas; and
bonding the at least one light emitting diode chip to the contact areas.

9. The method of claim 6, wherein further comprising laminating a second flexible shielding foil on the conductive pattern layer such that the conductive pattern layer is between the polymer foil and the second shielding foil.

10. The method of claim 6, further comprising laminating a luminescent foil over the at least one light emitting diode chip.
